(19) United States
(12) Patent Application Publication
(10) Pub. No.: US 2024/0389379 A1
(43) Pub. Date: Nov. 21, 2024

(54) LIGHT-EMITTING DEVICE AND DISPLAY PANEL

(71) Applicant: BOE Technology Group Co., Ltd., Beijing (CN)

(72) Inventors: Hui ZHOU, Beijing (CN); Yansong LI, Beijing (CN); Xiaobo DU, Beijing (CN); Guanyin WEN, Beijing (CN); Shuyun XU, Beijing (CN)

(21) Appl. No.: 18/693,532

(22) PCT Filed: Jul. 31, 2023
(86) PCT No.: PCT/CN2023/110106

§ 371 Date: Mar. 20, 2024

(30) Foreign Application Priority Data
Aug. 29, 2022 (CN) 202211040501.3

(51) Int. Cl. H10K 50/19; H10K 50/16; H10K 50/165; H10K 85/30; H10K 101/30; H10K 101/40

(52) U.S. Cl. CPC H10K 50/19; H10K 50/165; H10K 50/166; H10K 85/324; H10K 2101/30; H10K 2101/40

(57) ABSTRACT

Disclosed is a light-emitting device including a first electrode; a second electrode; a plurality of light-emitting units; and a charge separation/generation unit disposed between adjacent light-emitting units. Each charge separation/generation unit includes a first charge transmission sub-unit, a first charge generation sub-unit, a second charge generation sub-unit, and a second charge transmission sub-unit, sequentially arranged in a direction from the first electrode to the second electrode, the charge separation/generation unit satisfies that a transmittance is greater than 50% for visible light having a wavelength ranging from 380 nm to 480 nm, satisfies that a transmittance is greater than 70% for visible light having a wavelength ranging from 480 nm to 580 nm, and satisfies that a transmittance is greater than 75% for visible light having a wavelength ranging from 580 nm to 680 nm.

### CROSS-REFERENCE TO RELATED APPLICATIONS

The present application is a U.S. National Phase Entry of International Application No. PCT/CN2023/110106 having an international filing date of Jul. 31, 2023, which claims priority to Chinese Patent Application No. 202211040501.3, filed to the CNIPA on Aug. 29, 2022. Contents of the above-identified applications should be interpreted as being incorporated into the present application by reference.

### TECHNICAL FIELD

The present disclosure belongs to the field of display technologies, in particular to a light emitting device and a display panel.

### BACKGROUND

With development of display technologies, people have higher and higher requirements for display apparatuses. Compared with a Liquid Crystal Display (LCD) with mature technologies, display of an Organic Electroluminescence Display (OLED) has advantages of high color saturation, low drive voltage, wide viewing angle display, flexibility, a fast response speed, and a simple manufacturing process, etc., therefore, it gradually replaces a mainstream position of LCD display in the field of small-size display (such as mobile phones, watches, and other electronic products), and its product development trend is rapidly concentrated in the medium and large-size field.

A Tandem OLED light emitting device is an OLED in which multi-layer light emitting units in a light emitting device are connected in series through a charge generation layer and controlled by only one external power supply. Under a same voltage, compared with a single-layer OLED light emitting device, a Tandem OLED light emitting device has higher luminous brightness and current efficiency. The luminous brightness and current efficiency increase exponentially with increase of a quantity of light emitting units in series, and lifetime of a Tandem OLED is longer than that of a single-layer OLED under a same current density.

However, due to existence of multi-layer light emitting units in the Tandem OLED, compared with the single-layer OLED, a working voltage used is higher and there is a problem that a power efficiency is lower. Higher working voltage and lower power efficiency will affect power consumption of the Tandem OLED light emitting device adversely and reduce performance of the Tandem OLED light emitting device.

### SUMMARY

The present disclosure aims at solving at least one of technical problems existing in the prior art, and provides a light emitting device and a display panel.

In a first aspect, a technical solution adopted to solve a technical problem of the present disclosure is a light emitting device including a first electrode, a second electrode, a plurality of light emitting units disposed between the first electrode and the second electrode, and a charge separation generating unit disposed between adjacent light emitting units; the charge separation generating unit includes a first charge transport subunit, a first charge generation subunit, a second charge generation subunit, and a second charge transport subunit disposed in sequence along a direction from the first electrode to the second electrode; the first charge transport subunit, the first charge generation subunit, the second charge generation subunit, and the second charge transport subunit enable the charge separation generating unit to satisfy that a transmittance is greater than 68% when a wavelength of visible light is in a range of 380 nm to 480 nm; enable the charge separation generating unit to satisfy that a transmittance is greater than 85% when a wavelength of visible light is in a range of 480 nm to 580 nm; and enable the charge separation generating unit to satisfy that a transmittance is greater than 86% when a wavelength of visible light is in a range of 580 nm to 680 nm.

In some embodiments, the first charge generation subunit satisfies that a transmittance is greater than 85% when a wavelength of visible light is in the range of 380 nm to 480 nm; the first charge generation subunit satisfies that a transmittance is greater than 95% when a wavelength of visible light is in the range of 480 nm to 580 nm; the first charge generation subunit satisfies that a transmittance is greater than 96% when a wavelength of visible light is in the range of 580 nm to 680 nm.

In some embodiments, the second charge generation subunit satisfies that a transmittance is greater than 85% when a wavelength of visible light is in the range of 380 nm to 480 nm; the second charge generation subunit satisfies that a transmittance is greater than 95% when a wavelength of visible light is in the range of 480 nm to 580 nm; the second charge generation subunit satisfies that a transmittance is greater than 96% when a wavelength of visible light is in the range of 580 nm to 680 nm.

In some embodiments, the first charge generation subunit and the second charge generation subunit, which are stacked, serve as one layer of charge generation unit; the charge generation unit satisfies that a transmittance is greater than 75% when a wavelength of visible light is in the range of 380 nm to 480 nm; the charge generation unit satisfies that a transmittance is greater than 93% when a wavelength of visible light is in the range of 480 nm to 580 nm; the charge generation unit satisfies that a transmittance is greater than 95% when a wavelength of visible light is in the range of 580 nm to 680 nm.

In some embodiments, the first charge generation subunit includes a first host material and a first guest material doped in the first host material; the second charge generation subunit includes a second host material and a second guest material doped in the second host material; a doping concentration of the first guest material is between 0.4% and 2.0%; a doping concentration of the second guest material is between 0.5% and 1.5%.

In some embodiments, the first guest material includes a metal or metal salt whose work function orientation is in a range of 2 electron Volts (eV) to 3 eV.

In some embodiments, the first guest material includes at least one of Ytterbium (Yb), Lithium (Li), Cesium (Cs), lithium carbonate, or cesium carbonate.

In some embodiments, the second guest material includes an organic electronic type material and/or an inorganic metal oxide material.

In some embodiments, the organic electronic type material includes 2,3,6,7,10,11-hexocyano-1,4,5,8,9,12-hexazabenzophenanthrene (HATCN).

In some embodiments, the inorganic metal oxide material includes molybdenum oxide.

In some embodiments, the first charge transport subunit includes at least one layer of first electron transport layer; or, a first hole block layer and at least one layer of first electron transport layer disposed in sequence along the direction from the first electrode to the second electrode.

In some embodiments, the first charge generation subunit includes an N-type doped charge generation layer; a difference between a Lowest Unoccupied Molecular Orbital (LUMO) energy level of one first electron transport layer close to the N-type doped charge generation layer and a Lowest Unoccupied Molecular Orbital (LUMO) energy level of the N-type doped charge generation layer is between −0.2 eV and 0.2 eV.

In some embodiments, a Lowest Unoccupied Molecular Orbital (LUMO) energy level of one first electron transport layer close to the N-type doped charge generation layer is 0.06 eV.

In some embodiments, the first electron transport layer includes a plurality of layers; a difference between a Lowest Unoccupied Molecular Orbital (LUMO) energy level of each layer of the first electron transport layer and the Lowest Unoccupied Molecular Orbital (LUMO) energy level of the N-type doped charge generation layer is between −0.2 eV and 0.2 eV.

In some embodiments, a third host material of the first electron transport layer includes a nitrogen-containing heterocyclic derivative or a pyridine derivative; a third guest material doped in the third host material includes 8-hydroxyquinoline lithium or 8-hydroxyquinoline aluminum analog.

In some embodiments, a doping concentration of the third guest material is between 5% and 15%.

In some embodiments, the second charge transport unit includes a second hole transport layer and a second electron block layer that are sequentially disposed along a direction from the first electrode to the second electrode.

In some embodiments, a Highest Occupied Molecular Orbital (HOMO) energy level of the second electron block layer is greater than a Highest Occupied Molecular Orbital (HOMO) energy level of the second hole transport layer, and a difference between the Highest Occupied Molecular Orbital (HOMO) energy level of the second electron block layer and the Highest Occupied Molecular Orbital (HOMO) energy level of the second hole transport layer is less than 0.15 eV.

In some embodiments, the second host material is the same as a material of the second hole transport layer; the second charge generation subunit includes a P-type doped charge generation layer; a Highest Occupied Molecular Orbital (HOMO) energy level of the P-type doped charge generation layer is smaller than a Highest Occupied Molecular Orbital (HOMO) energy level of the second hole transport layer.

In some embodiments, the second host material is different from a material of the second hole transport layer; the second charge generation subunit includes a P-type doped charge generation layer; a Highest Occupied Molecular Orbital (HOMO) energy level of the P-type doped charge generation layer is larger than a Highest Occupied Molecular Orbital (HOMO) energy level of the second hole transport layer, and a difference between the Highest Occupied Molecular Orbital (HOMO) energy level of the P-type doped charge generation layer and the Highest Occupied Molecular Orbital (HOMO) energy level of the second hole transport layer is less than 0.15 eV.

In some embodiments, the first host material includes any one of substances selected from pyridine, azine ring, and imidazole analog.

In some embodiments, the second host material includes any one material selected from triphenylamine analog, biphenyl analog, arylamine analog, or carbazole analog.

In some embodiments, the light emitting unit includes an emitting layer and a sub-functional layer; the sub-functional layer includes at least one of a hole injection layer, an electron injection layer, a first hole transport layer, a second electron transport layer, a second hole block layer, and a first electron block layer.

In a second aspect, an embodiment of the present disclosure also provides a display panel including the light emitting device described in any of the above embodiments.

### BRIEF DESCRIPTION OF DRAWINGS

FIG. 1 is a schematic diagram of a structure of a light emitting device according to an embodiment of the present disclosure.

FIG. 2 is a schematic diagram of different transmittance of an N-type doped charge generation layer in a same visible light wavelength range according to an embodiment of the present disclosure.

FIG. 3 is a schematic diagram of comparison of current efficiencies of two N-type doped charge generation layers based on FIG. 2 according to an embodiment of the present disclosure.

FIG. 4 is a schematic diagram of comparison of a relationship between a current density and a voltage of two N-type doped charge generation layers based on FIG. 2 according to the embodiment of the present disclosure.

FIG. 5 is a schematic diagram of comparison of microcavity effects of two N-type doped charge generation layers based on FIG. 2 according to an embodiment of the present disclosure.

FIG. 6 is a schematic diagram of an exemplary light emitting device according to an embodiment of the present disclosure.

FIGS. 7a-7c are schematic diagrams of different situations of Lowest Unoccupied Molecular Orbital (LUMO) energy levels between three exemplary N-type doped charge generation layers and a first electron transport layer according to an embodiment of the present disclosure.

FIG. 8 is a schematic diagram of a structure in which a first electron transport layer and an N-type doped charge generation layer are provided with different LUMO energy level gaps according to an embodiment of the present disclosure.

FIG. 9 is a schematic diagram of comparison of a relationship between a current density and a voltage generated by setting two different LUMO energy levels based on the first electron transport layer and the N-type doped charge generation layer of FIG. 8 according to an embodiment of the present disclosure.

FIG. 10 is a schematic diagram of comparison of current efficiencies of two first electron transport layers based on FIG. 8 according to an embodiment of the present disclosure.

FIGS. 11a and 11b are schematic diagrams of different situations of Highest Occupied Molecular Orbital (HOMO) energy levels of two exemplary second hole transport layers and adjacent organic functional film layers according to an embodiment of the present disclosure.

FIGS. 12a and 12b are schematic diagrams of a structure in which different HOMO energy level gaps are set between a second hole transport layer and a second electron block layer according to an embodiment of the present disclosure.

FIG. 13 is a schematic diagram of comparison of a relationship between a current density and a voltage generated by setting two different HOMO energy levels based on the second hole transport layer and the second electron block layer of FIGS. 12a and 12b according to an embodiment of the present disclosure.

FIG. 14 is a schematic diagram of comparison of current efficiencies of two second hole transport layers based on FIGS. 12a and 12b according to an embodiment of the present disclosure.

Among them, reference numerals are as follows: light emitting device 100; first electrode 1; second electrode 2; light emitting unit 3; charge separation generating unit 4; first charge transport subunit 41; first charge generation subunit 42; second charge generation subunit 43; second charge transport subunit 44; Anode; hole injection layer HIL; first hole transport layer HTL1; first electron block layer EBL1; first emitting layer EML1; first hole block layer HBL1; first electron transport layer ETL1; N-type doped charge generation layer N-CGL; P-type doped charge generation layer P-CGL; second hole transport layer HTL2; second electron block layer EBL2; second emitting layer EML2; second hole block layer HBL2; second electron transport layer ETL2; electron injection layer EIL; Cathode.

### DETAILED DESCRIPTION

For the purpose, technical solutions and advantages of embodiments of the present disclosure to be clearer, the technical solutions of the embodiments of the present disclosure will be clearly and completely described below in conjunction with the accompanying drawings of the embodiments of the present disclosure, and it will be apparent that the described embodiments are only a part of the embodiments of the present disclosure, not all of them. Components of the embodiments of the present disclosure generally described and illustrated in the drawings herein may be arranged and designed in a variety of different configurations. Therefore, following detailed description of the embodiments of the present disclosure provided in the accompanying drawings is not intended to limit the scope of the claimed present disclosure, but merely represents selected embodiments of the present disclosure. Based on the embodiments of the present disclosure, all other embodiments obtained by a person of ordinary skill in the art without paying any inventive effort are within the scope of protection of the present disclosure.

Unless otherwise defined, technical terms or scientific terms used in the present disclosure should have meanings as commonly understood by those of ordinary skills in the art that the present disclosure belongs to. “First”, “second”, and similar words used in the present disclosure do not indicate any order, quantity, or importance, but are used only for distinguishing different components. Similarly, similar words such as “a”, “an”, or “the” do not denote a limitation on quantity, but rather denote presence of at least one. “Include”, “contain”, or similar words mean that elements or objects appearing before the words cover elements or objects listed after the words and their equivalents, but do not exclude other elements or objects. “Connect”, “couple”, or a similar word is not limited to a physical or mechanical connection, but may include an electrical connection, whether direct or indirect. “Upper”, “lower”, “left”, and “right”, etc., are used for representing relative positional relationships, and when an absolute position of a described object is changed, a relative positional relationship may also be correspondingly changed.

“Multiple or several” mentioned in the present disclosure refers to two or more. “And/or”, describing an association relationship between associated objects, means that there may be three relationships, for example, A and/or B, which may mean that there are three situations: A alone, A and B at the same time, and B alone. A character “/” generally indicates an “or” relationship between context associated objects.

A traditional OLED light emitting device is composed of a Hole Transport Layer (HTL), an Emitting Layer (EML), and an Electron Transport Layer (ETL), which are sandwiched between an anode electrode and a cathode electrode. In order to improve performance of an OLED light emitting device, multi-layer light emitting units have been designed one after another. For example, an organic functional layer including a Hole Transport Layer (HTL), an Electron Injection Layer (EIL), an Electron Block Layer (EBL), and a Hole Block Layer (HBL) has been continuously added. After that, a concept of a light emitting unit doped OLED has also been put forward. By optimizing a thickness of an organic functional layer, improving a preparation process, and using each organic functional layer, luminescent performance of an OLED light emitting device has been steadily improved.

In order to further improve performance of the OLED light emitting device, a concept of a Tandem OLED came into being. The Tandem OLED is an OLED in which multi-layer light-emitting units in a light emitting device are connected in series through a charge generation layer and controlled by only one external power supply. Under a same voltage, compared with a single-layer OLED light emitting device, a Tandem OLED light emitting device has higher luminous brightness and current efficiency. The luminous brightness and current efficiency increase exponentially with increase of a quantity of light emitting units in series, and lifetime of a Tandem OLED is longer than that of a single-layer OLED under a same current density. However, due to existence of multi-layer light emitting units in the Tandem OLED, compared with the single-layer OLED, a working voltage used is higher and there is a problem that a power efficiency is lower. Higher working voltage and lower power efficiency will affect power consumption of the Tandem OLED light emitting device adversely and reduce performance of the Tandem OLED light emitting device.

In addition, in the related art, in a structure of a Tandem OLED light emitting device, a Charge Generation Layer (CGL) between a first emitting layer EML1 and a second emitting layer EML2 is generally adopted to generate electrons and holes. After the electrons and holes are separated, the electrons are transmitted and injected to the first emitting layer EML1, and the holes are transmitted and injected to the second emitting layer EML2; thereafter, recombining with holes generated by the Anode at the first emitting layer EML1, thereby emitting light; at the second emitting layer EML2, recombining with electrons generated by the Cathode, thereby emitting light. Therefore, the Charge Generation Layer (CGL) is very important for performance of a Tandem device.

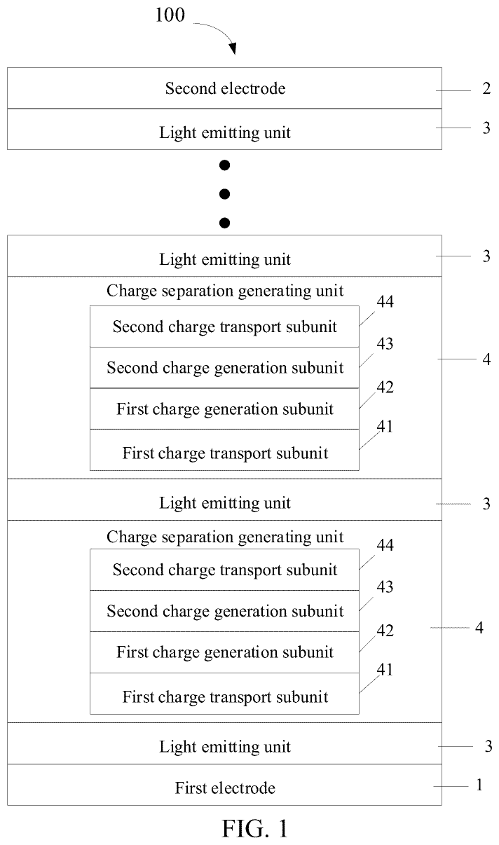

Based on this, an embodiment of the present disclosure provides a light emitting device, which optimizes a structure and limits a parameter of a charge separation generating unit, which is beneficial to generation, separation, injection, and transmission of charges, so as to improve performance of a Tandem light emitting device, such as reducing a working voltage of the Tandem light emitting device, improving a current efficiency and a power efficiency. FIG. 1 is a schematic diagram of a structure of a light emitting device according to an embodiment of the present disclosure. As shown in FIG. 1, a light emitting device 100 according to the embodiment of the present disclosure includes a first electrode 1, a second electrode 2, a plurality of light emitting units 3 disposed between the first electrode 1 and the second electrode 2, and a charge separation generating unit 4 disposed between adjacent light emitting units. Among them, the charge separation generating unit 4 includes a first charge transport subunit 41, a first charge generation subunit 42, a second charge generation subunit 43, and a second charge transport subunit 44 that are sequentially disposed along a direction pointing to the second electrode 2 from the first electrode 1.

Exemplarily, the first charge generation subunit 42 includes an N-type doped Charge Generation Layer (N-CGL), i.e., an N-type organic semiconductor. The second charge generation subunit 43 includes a P-type doped Charge Generation Layer (P-CGL), i.e., a P-type organic semiconductor. The N-type doped Charge Generation Layer (N-CGL) and the P-type doped Charge Generation Layer (P-CGL) may form a P/N junction structure.

According to the embodiment of the present disclosure, the first charge transport subunit 41, the first charge generation subunit 42, the second charge generation subunit 43, and the second charge transport subunit 44 in the charge separation generating unit are optimized in structure and limited in parameters, so that the charge separation generating unit 4 satisfies that a transmittance is greater than 50% when a wavelength of visible light is in a range of 380 nm to 480 nm; so that the charge separation generating unit 4 satisfies that a transmittance is greater than 70% when a wavelength of visible light is in a range of 480 nm to 580 nm; so that the charge separation generating unit 4 satisfies that a transmittance is greater than 75% when a wavelength of visible light is in a range of 580 nm to 680 nm. When the charge separation generating unit 4 satisfies transmittance of visible light in different wavelength ranges, a speed of charge generation by the first charge generation subunit 42 and the second charge generation subunit 43 can be improved, a speed of charge separation can be improved, a speed of charge injection into other film layers can be improved, a speed of charge transport by the first charge transport subunit 41 and the second charge transport subunit 44, and a speed of charge injection into other film layers can be improved, thereby improving performance of the light emitting device 100, reducing a working voltage, and improving a current efficiency and a power efficiency.

Preferably, in the present disclosure, a first charge transport subunit, a first charge generation subunit, a second charge generation subunit, and a second charge transport subunit are disposed, so that the charge separation generating unit satisfies that a transmittance is greater than 68% when a wavelength of visible light is in a range of 380 nm to 480 nm; so that the charge separation generating unit satisfies that a transmittance is greater than 85% when a wavelength of visible light is in a range of 480 nm to 580 nm; so that the charge separation generating unit satisfies that a transmittance is greater than 86% when a wavelength of visible light is in a range of 580 nm to 680 nm.

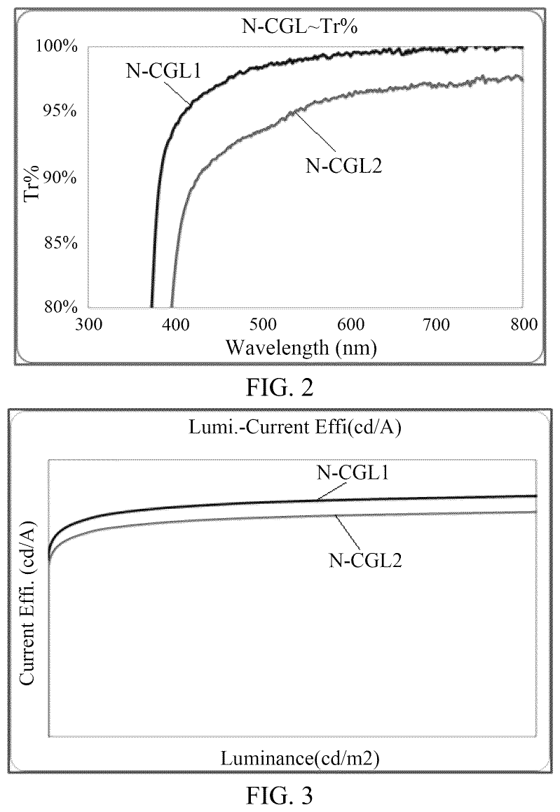

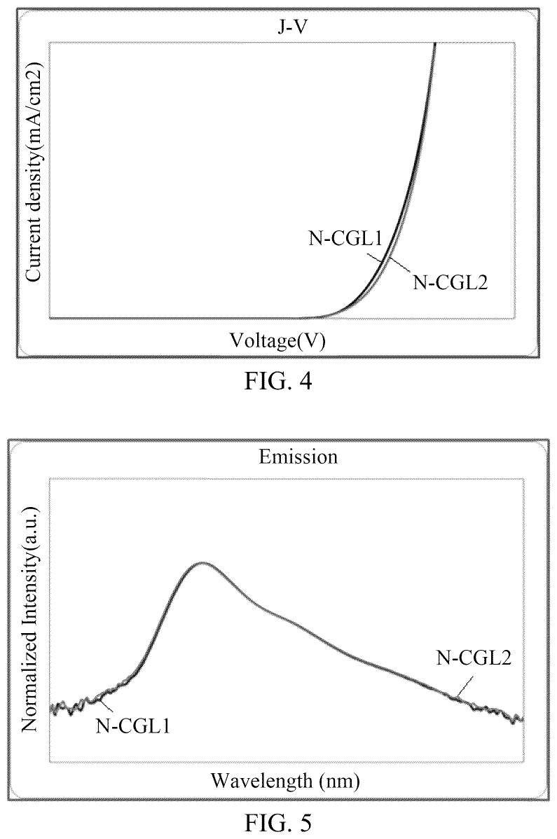

In some embodiments, FIG. 2 is a schematic diagram of different transmittance of an N-type doped charge generation layer in a same visible light wavelength range according to an embodiment of the present disclosure, wherein the abscissa represents a Wavelength of visible light (unit: nanometer (nm)) and the ordinate represents a transmittance Tr %. FIG. 3 is a schematic diagram of comparison of current efficiencies of two N-type doped charge generation layers based on FIG. 2 according to an embodiment of the present disclosure, wherein the abscissa represents Luminance (unit: Candeira/square meter (cd/m²)), the ordinate represents a Current efficiency (unit: Candeira/angstrom (cd/A)). FIG. 4 is a schematic diagram of comparison of a relationship between a current density and a voltage of two N-type doped charge generation layers based on FIG. 2 according to the embodiment of the present disclosure, wherein the abscissa represents a voltage (unit: Volt (V)) and the ordinate represents a Current density (unit: mA/square centimeter (mA/cm²)). FIG. 5 is a schematic diagram of comparison of microcavity effects of two N-type doped charge generation layers based on FIG. 2 according to an embodiment of the present disclosure, wherein the abscissa represents a Wavelength of visible light (unit: nanometer (nm)) and the ordinate represents a luminous intensity (Normalized intensity) (arbitrary unit, abbreviated a.u.).

As shown in FIG. 2, taking two N-type doped charge generation layers N-CGL with different transmittance as an example, an N-type doped charge generation layer N-CGL1 and an N-type doped charge generation layer N-CGL2 have different transmittance in a region of visible light, but remaining influences are the same. The “remaining influences” herein include, for example, influences of materials, energy levels, mobility, etc. of N-type doped charge generation layers N-CGL. Among them, the N-type doped charge generation layers N-CGL have a same material, including a same first host material, a same first guest material, a same doping concentration of the first guest material, etc. Among them, the doping concentration may be understood as a molar mass ratio between a guest material and a host material.

Specifically, the first charge generation subunit 42 satisfies that a transmittance is greater than 85% when a wavelength of visible light is in a range of 380 nm to 480 nm; the first charge generation subunit 42 satisfies that a transmittance is greater than 95% when a wavelength of visible light is in a range of 480 nm to 580 nm. The first charge generation subunit 42 satisfies that a transmittance is greater than 96% when a wavelength of visible light is in a range of 580 nm to 680 nm. The N-type doped charge generation layer N-CGL1 shown in FIG. 2 satisfies transmittance conditions in various wave bands of visible light satisfied by the first charge generation subunit 42, while the N-type doped charge generation layer N-CGL2 shown in FIG. 2 does not satisfy the transmittance conditions in various wave bands of visible light.

As shown in FIG. 3, a current efficiency of the N-type doped charge generation layer N-CGL1 is higher than that of the N-type doped charge generation layer N-CGL2 under a condition that transmittance of the N-type doped charge generation layer N-CGL1 and the N-type doped charge generation layer N-CGL2 satisfy different conditions in a wavelength range of visible light. As shown in FIG. 4, current densities of the N-type doped charge generation layer N-CGL1 and the N-type doped charge generation layer N-CGL2 at different voltages are similar, that is, the N-type doped charge generation layer N-CGL1 and the N-type doped charge generation layer CGL2 have less influence on a current and a voltage of the light emitting device 100. It may be reflected herein that energy levels and mobility of the N-type doped charge generation layer N-CGL1 and the N-type doped charge generation layer N-CGL2 are the same. As shown in FIG. 5, it reflects that luminous intensities of the N-type doped charge generation layer N-CGL1 and the N-type doped charge generation layer N-CGL2 are the same at different visible light wavelengths, that is, microcavity effects are the same. It may be seen that under experimental verification, transmittance conditions of the N-type doped charge generation layer N-CGL1 in various wavelength ranges of visible light are main factors affecting performance of the Tandem device, that is, the first charge generation subunit 42 satisfies that a transmittance is greater than 85% when a wavelength of visible light is in a range of 380 nm to 480 nm; the first charge generation subunit 42 satisfies that a transmittance is greater than 95% when a wavelength of visible light is in a range of 480 nm to 580 nm; the first charge generation subunit 42 satisfies that a transmittance is greater than 96% when a wavelength of visible light is in a range of 580 nm to 680 nm, so that a current efficiency can be improved and performance of the Tandem light emitting device 100 may be improved.

In some embodiments, the second charge generation subunit 43 satisfies same transmittance conditions described above as the first charge generation subunit 42. Specifically, the second charge generation subunit 43 satisfies that a transmittance is greater than 85% when a wavelength of visible light is in a range of 380 nm to 480 nm; the second charge generation subunit 43 satisfies that a transmittance is greater than 95% when a wavelength of visible light is in a range of 480 nm to 580 nm. The second charge generation subunit 43 satisfies that a transmittance is greater than 96% when a wavelength of visible light is in a range of 580 nm to 680 nm. Similar to the above-described experimental procedures in FIG. 2 to FIG. 5, it may be known from experimental verification that when the second charge generation subunit 43 satisfies the above-mentioned transmittance conditions in various wavelength ranges of visible light, a current efficiency can be improved and performance of the Tandem light emitting device 100 can be improved.

In some embodiments, the first charge generation subunit 42 and the second charge generation subunit 43, which are stacked, serve as one layer of charge generation unit. Exemplarily, the first charge generation subunit 42 includes an N-type doped Charge Generation Layer (N-CGL). The second charge generation subunit 43 includes a P-type doped Charge Generation Layer (P-CGL). The charge generation unit, i.e. the N-type doped Charge Generation Layer (N-CGL) and the P-type doped Charge Generation Layer (P-CGL) which are stacked, is configured to be able to form a P/N junction structure.

The charge generation unit satisfies that a transmittance is greater than 75% when a wavelength of visible light is in a range of 380 nm to 480 nm; the charge generation unit satisfies that a transmittance is greater than 93% when a wavelength of visible light is in a range of 480 nm to 580 nm; the charge generation unit satisfies that a transmittance is greater than 95% when a wavelength of visible light is in a range of 580 nm to 680 nm. Similar to the above-described experimental procedures in FIG. 2 to FIG. 5, it may be known from experimental verification that when the charge generation unit satisfies the above-mentioned transmittance conditions in various wavelength ranges of visible light, a current efficiency can be improved and performance of the Tandem light emitting device 100 can be improved.

In some embodiments, the first charge generation subunit 42 includes a first host material and a first guest material doped in the first host material; the second charge generation subunit 43 includes a second host material and a second guest material doped in the second host material. A doping concentration of the first guest material is between 0.4% and 2.0%; a doping concentration of the second guest material is between 0.5% and 1.5%.

Since a host material, a guest material, and a doping concentration of the guest material are all factors affecting a transmittance of the first charge generation subunit 42, the N-type doped charge generation layer N-CGL1 and the N-type doped charge generation layer N-CGL2 in the above-described embodiments may further change the transmittance by adjusting a first host material, a first guest material, or a doping concentration of the first guest material. For the second charge generation subunit 43, it has a same manner of adjusting a transmittance as the first charge generation subunit 42, which will not be repeated in the embodiments of the present disclosure.

Exemplarily, a doping concentration of the second guest material of the N-type doped charge generation layer N-CGL1 is between 0.5% and 1.5%. The N-type doped charge generation layer N-CGL1 and the N-type doped charge generation layer N-CGL2 need to ensure that at least one of respectively corresponding first host material, first guest material, and doping concentration of the first guest material is different.

In some embodiments, the first guest material includes a metal or a metal salt whose work function orientation is in a range of 2 electron Volts (eV) to 3 eV, i.e. a low work function metal or a low work function metal salt, such as at least one of Ytterbium (Yb), Lithium (Li), Cesium (Cs), lithium carbonate, or cesium carbonate.

In some embodiments, the second guest material includes an organic electronic type material and/or an inorganic metal oxide material. Among them, the organic electronic type material may include HATCN, which is 2,3,6,7,10, 11-hexocyano-1,4,5,8,9,12-hexazabenzophenanthrene. The inorganic metal oxide material may include Molybdenum Oxide (MoO).

Exemplarily, a low work function metal (or metal salt) is doped into the first host material and a doping concentration is between 0.4% and 2.0%, so that the first charge generation subunit 42 can satisfy that a transmittance is greater than 85% when a wavelength of visible light is in a range of 380 nm to 480 nm; the first charge generation subunit 42 can satisfy that a transmittance is greater than 95% when a wavelength of visible light is in a range of 480 nm to 580 nm; the first charge generation subunit 42 can satisfy that a transmittance is greater than 96% when a wavelength of visible light is in a range of 580 nm to 680 nm, thereby improving a speed of charge generation by the first charge generation subunit 42, a speed of charge separation by the first charge generation subunit 42, and a speed of charge injection into other film layers, etc., thereby improving performance of the light emitting device 100, reducing a working voltage of the light emitting device 100, and improving a current efficiency and a power efficiency.

Exemplarily, an organic electronic type material (or an inorganic metal oxide material) is doped into the second host material and a doping concentration is between 0.5% and 1.5%, so that the second charge generation subunit 43 can satisfy that a transmittance is greater than 85% when a wavelength of visible light is in a range of 380 nm to 480 nm; the second charge generation subunit 43 can satisfy that a transmittance is greater than 95% when a wavelength of visible light is in a range of 480 nm to 580 nm; the second charge generation subunit 43 can satisfy that a transmittance is greater than 96% when a wavelength of visible light is in a range of 580 nm to 680 nm, thereby improving a speed of charge generation by the second charge generation subunit 43, a speed of charge separation by the second charge generation subunit 43, and a speed of charge injection into other film layers, etc., thereby improving performance of the light emitting device 100, reducing a working voltage of the light emitting device 100, and improving a current efficiency and a power efficiency.

Exemplarily, the first charge generation subunit 42 and the second charge generation subunit 43, which are stacked, serve as one layer of charge generation unit. A low work function metal (or metal salt) is doped into the first host material and a doping concentration is between 0.4% and 2.0%, and an organic electronic type material (or an inorganic metal oxide material) is doped into the second host material and a doping concentration is between 0.5% and 1.5%, so that the charge generation unit can satisfy that a transmittance is greater than 75% when a wavelength of visible light is in a range of 380 nm to 480 nm; the charge generation unit can satisfy that a transmittance is greater than 93% when a wavelength of visible light is in a range of 480 nm to 580 nm; the charge generation unit can satisfy that a transmittance is greater than 95% when a wavelength of visible light is in a range of 580 nm to 680 nm, thereby improving a speed of charge generation by the charge generation subunit, a speed of charge separation by the charge generation subunit, and a speed of charge injection into other film layers, etc., thereby improving performance of the light emitting device 100, reducing a working voltage of the light emitting device 100, and improving a current efficiency and a power efficiency.

In some embodiments, the first host material may include any one of substances selected from pyridine, azine ring, and imidazole analog.

For example, a material selected from a following general formula as a basic structure.

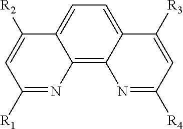

Among them, R₁, R₂, R₃, and R₄ are independently selected from any one of H, F, CI, Br, alkyl, aryl, heteroalkyl, and heteroaryl.

Exemplary, the first host material of the N-type doped Charge Generation Layer (N-CGL) is an electron transport material of the above general formula and the first guest material is a low work function metal; a doping concentration of the first guest material is 1.2%, so that the N-type doped Charge Generation Layer (N-CGL) can satisfy that a transmittance is greater than 85% when a wavelength of visible light is in a range of 380 nm to 480 nm; the first charge generation subunit 42 can satisfy that a transmittance is greater than 95% when a wavelength of visible light is in a range of 480 nm to 580 nm; the first charge generation subunit 42 can satisfy that a transmittance is greater than 96% when a wavelength of visible light is in a range of 580 nm to 680 nm. At the same time, electron mobility of the N-type doped Charge Generation Layer (N-CGL) is ensured to be greater than 10⁻⁴Cm²/V.S. Thereby, speeds of charge generation, injection, and transport of the N-type doped Charge Generation Layer (N-CGL) are improved, and performance of the light emitting device 100 is further improved.

In some embodiments, the second host material may include any one material selected from triphenylamine analog, biphenyl analog, arylamine analog, or carbazole analog. For example, the second host material may be selected from a material with an NPB general formula as a basic structure, NPB is structural N,N′-diphenyl-N,N′-(1-naphthyl)-1,1′-biphenyl-4,4′-diamine, and its chemical formula is as follow.

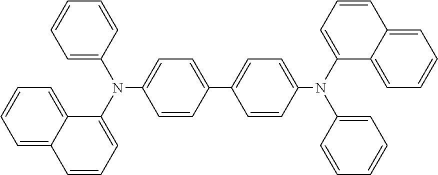

In the embodiment of the present disclosure, by optimizing structures and limiting parameters of the first charge generation subunit 42 and the second charge generation subunit 43, such as selection of a host material and a guest material, and a limitation on a doping concentration of the guest material, the first charge generation subunit 42 and the second charge generation subunit 43 may respectively meet a preset transmittance condition corresponding to each visible light wavelength range (the “preset transmittance condition” here may be understood as, for example, for the first charge generation subunit 42, a condition that visible light is in a wavelength range of 380 nm to 480 nm and a transmittance is greater than 68% is satisfied, a condition that visible light is in a wavelength range of 480 nm to 580 nm and a transmittance is greater than 85% is satisfied, and a condition that visible light is in a wavelength range of 580 nm to 680 nm and a transmittance is greater than 86% is satisfied). It may be known through experimental verification, under a condition that the first charge generation subunit 42 and the second charge generation subunit 43 respectively meet a preset transmittance condition corresponding to each visible light wavelength range, speeds of charge generation by the first charge generation subunit 42 and the second charge generation subunit 43 can be increased, speeds of charge separation can be increased, and speeds of charge injection into other film layers can be increased, thereby improving performance of the light emitting device 100, reducing a working voltage, and improving a current efficiency and a power efficiency.

In some embodiments, a light emitting unit 3 includes an Emitting Layer (EML) and a sub-functional layer; the sub-functional layer includes at least one of a Hole Injection Layer (HIL), an Electron Injection Layer (EIL), a first hole transport layer HTL1, a second electron transport layer ETL2, a second hole block layer HBL2, and a first electron block layer EBL1.

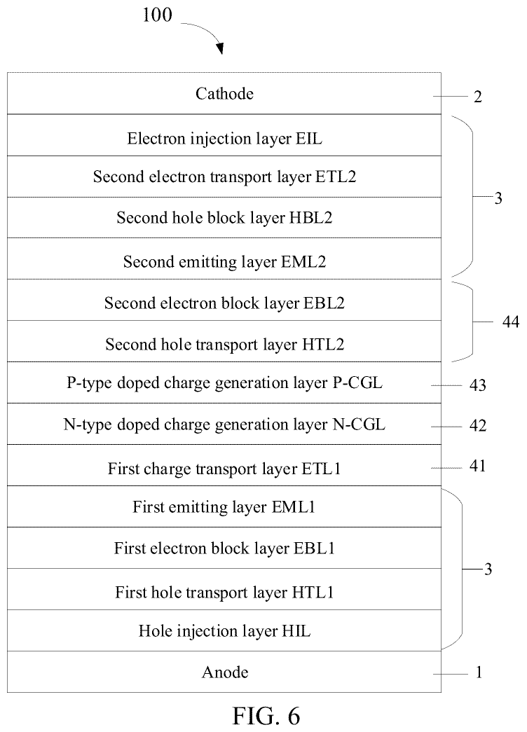

An embodiment of the present disclosure is illustrated by taking a case that the light emitting device 100 contains two light emitting units as an example. FIG. 6 is a schematic diagram of an exemplary light emitting device according to an embodiment of the present disclosure, as shown in FIG. 6, the light emitting unit 3 close to the first electrode 1 includes a Hole Injection Layer (HIL), a first hole transport layer HTL1, a first electron block layer EBL1, and a first emitting layer EML1 disposed in sequence along a direction pointing to the second electrode 2 from the first electrode 1; the first charge transport subunit 41 includes a first electron transport layer ETL1; the first charge generation subunit 42 includes an N-type doped Charge Generation Layer (N-CGL); the second charge generation subunit 43 includes a P-type doped Charge Generation Layer (P-CGL); the second charge transport subunit 44 includes a second hole transport layer HTL2 and a second electron block layer EBL2 that are sequentially disposed along a direction pointing to the second electrode 2 from the first electrode 1; the light emitting unit 3 close to the second electrode 2 includes a second emitting layer EML2, a second hole block layer HBL2, a second electron transport layer ETL2, and an Electron Injection Layer (EIL) disposed sequentially along a direction pointing to the second electrode 2 from the first electrode 1. In the following, recombination of electrons and holes in an emitting layer is introduced in detail.

Electrons generated at an interface between the N-type doped Charge Generation Layer (N-CGL) and the P-type doped Charge Generation Layer (P-CGL) are transmitted to the first emitting layer EML1. Specifically, electrons and holes are generated at the interface between the N-type doped Charge Generation Layer (N-CGL) and the P-type doped Charge Generation Layer (P-CGL). The N-type doped Charge Generation Layer (N-CGL) and the P-type doped Charge Generation Layer (P-CGL) work together to separate the electrons and holes, wherein the N-type doped Charge Generation Layer (N-CGL) acquires electrons and injects them into the first electron transport layer ETL1, which transmits the electrons to the first emitting layer EML1.

Holes generated by the first electrode 1 (i.e., an Anode) is transmitted to the first emitting layer EML1, specifically, the Hole Injection Layer (HIL) injects the holes generated by the Anode to the first hole transport layer HTL1, the first hole transport layer HTL1 transmits the holes to the first electron block layer EBL1, and the first electron block layer EBL1 is configured to block electrons, and transmits the received holes to the first emitting layer EML1.

Holes generated at an interface between the N-type doped Charge Generation Layer (N-CGL) and the P-type doped Charge Generation Layer (P-CGL) are transmitted to the second emitting layer EML2, specifically, the N-type doped Charge Generation Layer (N-CGL) and the P-type doped Charge Generation Layer (P-CGL) work together to separate electrons and holes, wherein the P-type doped Charge Generation Layer (P-CGL) acquires holes and injects them into the second hole transport layer HTL2, the second hole transport layer HTL2 transmits holes to the second electron block layer EBL2, and the second electron block layer EBL2 is configured to block electrons and transmit the received holes to the second emitting layer EML2.

Electrons generated by the second electrode 2 (i.e., the Cathode) are transmitted to the second emitting layer EML2. Specifically, the Electron Injection Layer (EIL) injects the electrons generated by the Cathode to the second electron transport layer ETL2, he second electron transport layer ETL2 transmits the electrons to the second hole block layer HBL2, and the second hole block layer HBL2 is configured to block holes and transmit the received electrons to the second emitting layer EML2.

According to the above electron and hole transport processes, it may be understood that the N-type doped Charge Generation Layer (N-CGL) and the first electron transport layer ETL1, two organic functional films, mainly play the role of effective electron injection and effective electron separation; the P-type doped Charge Generation Layer (P-CGL) and the second hole transport layer HTL2 play the role of effective hole injection and effective hole separation. Therefore, it may be seen that the N-type doped Charge Generation Layer (N-CGL) and the first electron transport layer ETL1, two organic functional films, have a great influence on luminescence of the first emitting layer EML1, and the N-type doped Charge Generation Layer (N-CGL) and the second hole transport layer HTL2 have a great influence on luminescence of the second emitting layer EML2, that is, on performance of the light emitting device 100.

Based on this, on a basis of the above embodiments, the present disclosure further optimizes structures of the first charge transport subunit 41 and the second charge transport subunit 44 to improve a charge transport speed, achieve optimal recombination of electrons and holes, and thereby improve performance of the Tandem light emitting device 100. Refer specifically to following embodiments.

In some embodiments, the first charge transport subunit 41 includes at least one layer of the first electron transport layer ETL1; or, the first hole block layer HBL1 and at least one layer of the first electron transport layer ETL1 are sequentially disposed along a direction pointing to the second electrode 2 from the first electrode 1.

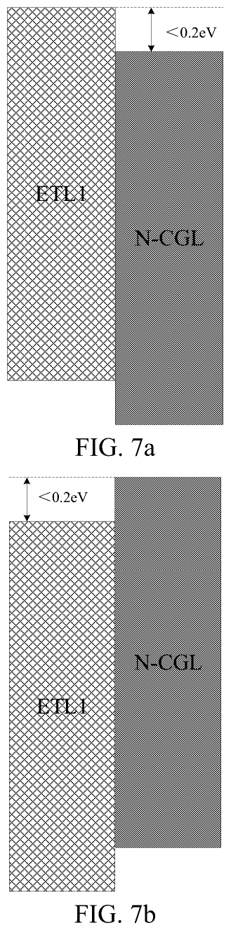

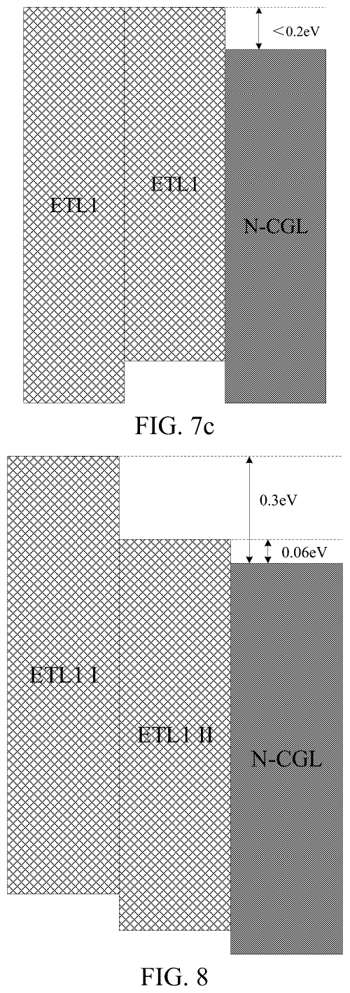

Exemplarily, at least one layer of the first electron transport layer ETL1 may be two layers of the first electron transport layer ETL11 and the first electron transport layer ETL12 stacked adjacent to each other, as shown in FIG. 7c. FIG. 6 shows an example in which the first charge transport subunit 41 includes only one layer of the first electron transport layer ETL1.

FIGS. 7a-7c are schematic diagrams of different situations of Lowest Unoccupied Molecular Orbital (LUMO) energy levels between three exemplary N-type doped charge generation layers and a first electron transport layer according to an embodiment of the present disclosure.

As shown in FIGS. 6 and 7a-7c, a difference between a Lowest Unoccupied Molecular Orbital (LUMO) energy level of a first electron transport layer ETL1 close to the N-type doped Charge Generation Layer (N-CGL) and a Lowest Unoccupied Molecular Orbital (LUMO) energy level of the N-type doped Charge Generation Layer (N-CGL) is between −0.2 eV and 0.2 eV. Among them, FIG. 7a shows a case that a Lowest Unoccupied Molecular Orbital (LUMO) energy level of a first electron transport layer ETL1 close to the N-type doped Charge Generation Layer (N-CGL) is larger than the Lowest Unoccupied Molecular Orbital (LUMO) energy level of the N-type doped Charge Generation Layer (N-CGL), but a difference between the two LUMO energy levels does not exceed 0.2 eV. FIG. 7b shows a case that a Lowest Unoccupied Molecular Orbital (LUMO) energy level of a first electron transport layer ETL1 close to the N-type doped Charge Generation Layer (N-CGL) is smaller than the Lowest Unoccupied Molecular Orbital (LUMO) energy level of the N-type doped Charge Generation Layer (N-CGL), but a difference between the two LUMO energy levels does not exceed 0.2 eV. FIG. 7c shows a case of two layers of the first electron transport layer ETL1, wherein a LUMO energy level of a first electron transport layer ETL1 close to the N-type doped Charge Generation Layer (N-CGL) is greater than a LUMO energy level of the N-type doped Charge Generation Layer (N-CGL), and a difference between the two LUMO energy levels does not exceed 0.2 eV. A LUMO energy level of a first electron transport layer ETL1 far away from the N-type doped Charge Generation Layer (N-CGL) may not be limited whether it is greater than the LUMO energy level of the N-type doped Charge Generation Layer (N-CGL), and only a difference between the LUMO energy level of the first electron transport layer ETL1 and the LUMO energy level of the N-type doped Charge Generation Layer (N-CGL) needs to be ensured to be between −0.2 eV and 0.2 eV. A difference between a Lowest Unoccupied Molecular Orbital (LUMO) energy level of each first electron transport layer ETL1 in the first charge transport subunit 41 and the Lowest Unoccupied Molecular Orbital (LUMO) energy level of the N-type doped Charge Generation Layer (N-CGL) is between −0.2 eV and 0.2 eV, which can improve a speed of charge transmission of the N-type doped Charge Generation Layer (N-CGL) and a speed of charge injection into other film layers, thereby improving performance of the light emitting device 100, reducing a working voltage, and improving a current efficiency and a power efficiency. Preferably, a Lowest Unoccupied Molecular Orbital (LUMO) energy level of a first electron transport layer close to the N-type doped charge generation layer is 0.06 eV.

In some embodiments, the first electron transport layer includes a plurality of layers; a difference between a Lowest Unoccupied Molecular Orbital (LUMO) energy level of each first electron transport layer and the Lowest Unoccupied Molecular Orbital (LUMO) energy level of the N-type doped charge generation layer is between −0.2 eV and 0.2 eV. Compared with a situation that a difference between a Lowest Unoccupied Molecular Orbital (LUMO) energy level of a first electron transport layer only close to the N-type doped charge generation layer among the plurality of layers of the first electron transport layer and the Lowest Unoccupied Molecular Orbital (LUMO) energy level of the N-type doped charge generation layer is between −0.2 eV and 0.2 eV, a speed of charge transmission of the N-type doped Charge Generation Layer (N-CGL) is further improved, a speed of charge injection into other film layers is improved, thereby improving performance of the light emitting device 100, reducing a working voltage, and improving a current efficiency and a power efficiency.

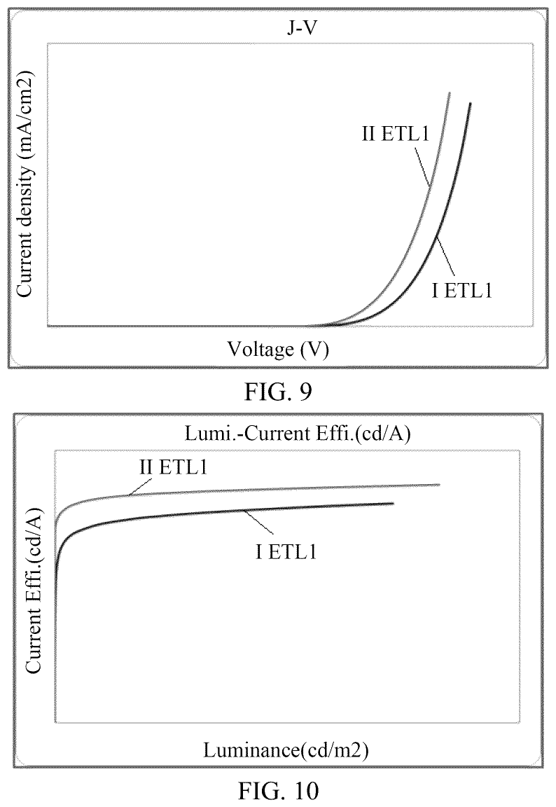

The above conclusions are further verified by experiments, FIG. 8 is a schematic diagram of a structure in which a first electron transport layer and an N-type doped charge generation layer are provided with different LUMO energy level gaps according to an embodiment of the present disclosure; FIG. 9 is a schematic diagram of comparison of a relationship between a current density and a voltage generated by setting two different LUMO energy levels based on the first electron transport layer and the N-type doped charge generation layer of FIG. 8 according to an embodiment of the present disclosure; FIG. 10 is a schematic diagram of comparison of current efficiencies of two first electron transport layers based on FIG. 8 according to an embodiment of the present disclosure.

As shown in FIG. 8, wherein a difference between a LUMO energy level of a first electron transport layer ETL1 II and a LUMO energy level of the N-type doped Charge Generation Layer (N-CGL) is 0.06 eV, i.e. less than 0.2 eV; a difference between a LUMO energy level of a first electron transport layer ETL1 I and the LUMO energy level of the N-type doped Charge Generation Layer (N-CGL) is 0.3 eV, i.e. greater than 0.2 eV.

As shown in FIGS. 8 and 9, current densities of the first electron transport layer ETL1 II and the first electron transport layer ETL1 I are quite different under different voltages. Among them, compared with the first electron transport layer ETL1 I, a current density of the first electron transport layer ETL1 II is higher than that of the first electron transport layer ETL1 I under a same voltage, which can indicate that electron mobility of the first electron transport layer ETL1 II is greater, that is, speeds of electron injection and electron transmission of the first charge transport subunit 41 are improved. Under a same current density, performance of the Tandem light emitting device 100 is reduced by 4% compared with a working voltage before optimization.

As shown in FIGS. 8 and 10, for the first electron transport layer ETL1 II and the first electron transport layer ETL1 I, a current efficiency of the first electron transport layer ETL1 II is higher than that of the first electron transport layer ETL1 I under same brightness, and a current efficiency of a light emitting device 100 having the first electron transport layer ETL1 II is improved by 8% compared with a current efficiency of a light emitting device 100 having the first electron transport layer ETL1 I.

In some embodiments, electron mobility of the first electron transport layer ETL1 also depends on a material of the first electron transport layer ETL1, and a third host material of the first electron transport layer ETL1 provided in the present disclosure includes a nitrogen-containing heterocyclic derivative or a pyridine derivative; a third guest material doped in the third host material includes 8-hydroxyquinoline lithium or 8-hydroxyquinoline aluminum analog. Among them, a doping concentration of the third guest material is between 5% and 15%. For example, the doping concentration of the third guest material is 10%. A thickness of ETL1 may be in a range of 3 nm to 17 nm, and the thickness of ETL1 is preferably 10 nm. The first electron transport layer ETL1 is made of the above-mentioned materials, which can ensure that electron mobility of the first electron transport layer ETL1 is greater than 10⁻⁶ Cm²/V.S. If there are a plurality of layers of the first electron transport layer ETL1, each layer of the first electron transport layer ETL1 may be adjusted according to the above adjustment mode to ensure that electron mobility of each layer of the electron transport layer ETL1 is greater than 10⁻⁶ Cm²/V.S.

In some embodiments, as shown in FIG. 6, the second charge transport subunit 44 includes a second hole transport layer HTL2 and a second electron block layer EBL2 that are sequentially disposed along a direction pointing to the second electrode 2 from the first electrode 1.

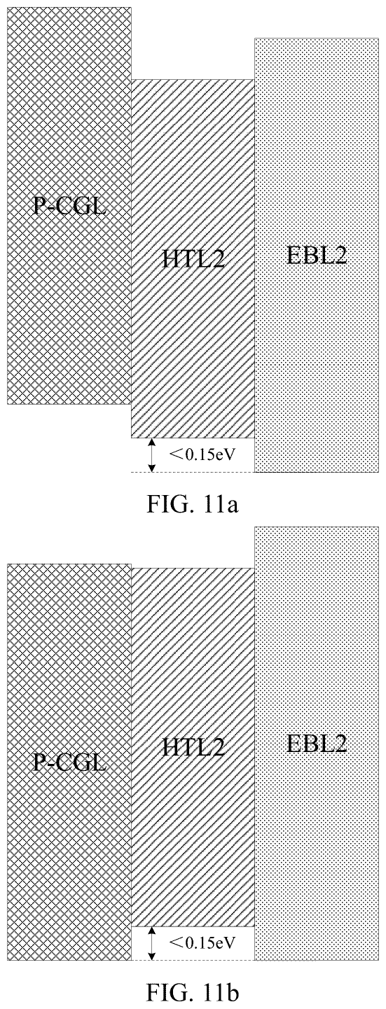

In some embodiments, FIGS. 1la and 11b are schematic diagrams of different situations of Highest Occupied Molecular Orbital (HOMO) energy levels of two exemplary second hole transport layers and adjacent organic functional film layers according to an embodiment of the present disclosure. As shown in FIGS. 11a and 11b, for the second electron block layer EBL2 adjacent to the second hole transport layer HTL2, specifically, a Highest Occupied Molecular Orbital (HOMO) energy level of the second electron block layer EBL2 is greater than a Highest Occupied Molecular Orbital (HOMO) energy level of the second hole transport layer HTL2, and a difference between the Highest Occupied Molecular Orbital (HOMO) energy level of the second electron block layer EBL2 and the Highest Occupied Molecular Orbital (HOMO) energy level of the second hole transport layer HTL2 is less than 0.15 eV. Here, by reasonably optimizing the difference between the HOMO energy level of the second hole transport layer HTL2 and the HOMO energy level of the second electron block layer EBL2, a speed of hole transmission of the second hole transport layer HTL2 can be improved, and a speed of hole injection into the second electron block layer EBL2 can be improved, thereby improving performance of the light emitting device 100, reducing a working voltage, and improving a current efficiency and a power efficiency.

A material of the second electron block layer EBL2 and a material of the second hole transport layer HTL2 in the embodiment of the present disclosure may be close to a host material of the P-type doped Charge Generation Layer (P-CGL), that is, close to a second host material.

For the P-type doped Charge Generation Layer (P-CGL) adjacent to the second hole transport layer HTL2, specifically, as shown in FIG. 11a, if the second host material is the same as the material of the second hole transport layer HTL2, a Highest Occupied Molecular Orbital (HOMO) energy level of the P-type doped Charge Generation Layer (P-CGL) is smaller than a Highest Occupied Molecular Orbital (HOMO) energy level of the second hole transport layer HTL2, and a difference between the Highest Occupied Molecular Orbital (HOMO) energy level of the P-type doped Charge Generation Layer (P-CGL) and the Highest Occupied Molecular Orbital (HOMO) energy level of the second hole transport layer HTL2 is smaller than 0.15 eV, that is, a value obtained by subtracting the HOMO energy level of the P-type doped Charge Generation Layer (P-CGL) from the HOMO energy level of the second hole transport layer HTL2 is not greater than or equal to 0.15 eV. As shown in FIG. 11b, if the second host material is different from the material of the second hole transport layer HTL2, the Highest Occupied Molecular Orbital (HOMO) energy level of the P-type doped Charge Generation Layer (P-CGL) is greater than the Highest Occupied Molecular Orbital (HOMO) energy level of the second hole transport layer HTL2, and a difference between the Highest Occupied Molecular Orbital (HOMO) energy level of the P-type doped Charge Generation Layer (P-CGL) and the Highest Occupied Molecular Orbital (HOMO) energy level of the second hole transport layer HTL2 is less than 0.15 eV, that is, a value obtained by subtracting the HOMO energy level of the second hole transport layer HTL2 from the HOMO energy level of the P-type doped Charge Generation Layer (P-CGL) is not greater than or equal to 0.15 eV.

Here, determining whether the second host material is the same as the material of the second hole transport layer HTL2, and reasonably optimizing the difference between the HOMO energy level of the P-type doped Charge Generation Layer (P-CGL) and the HOMO energy level of the second hole transport layer HTL2, a speed of hole transmission of the second hole transport layer HTL2 can be improved, thereby improving performance of the light emitting device 100, reducing a working voltage, and improving a current efficiency and a power efficiency.

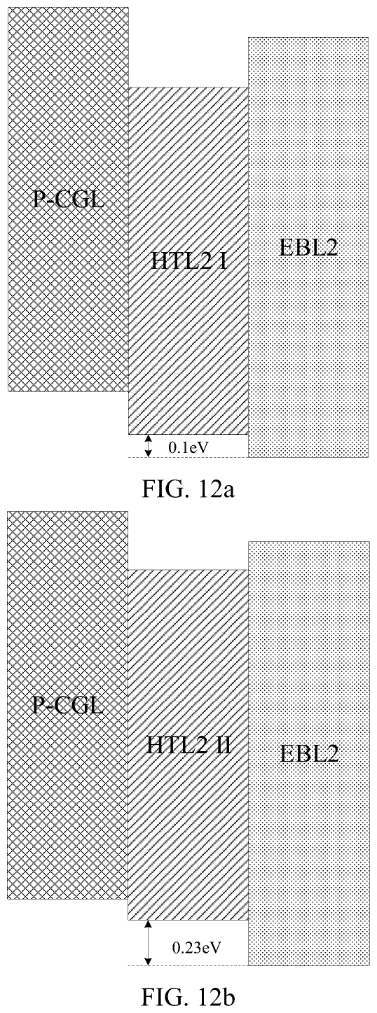

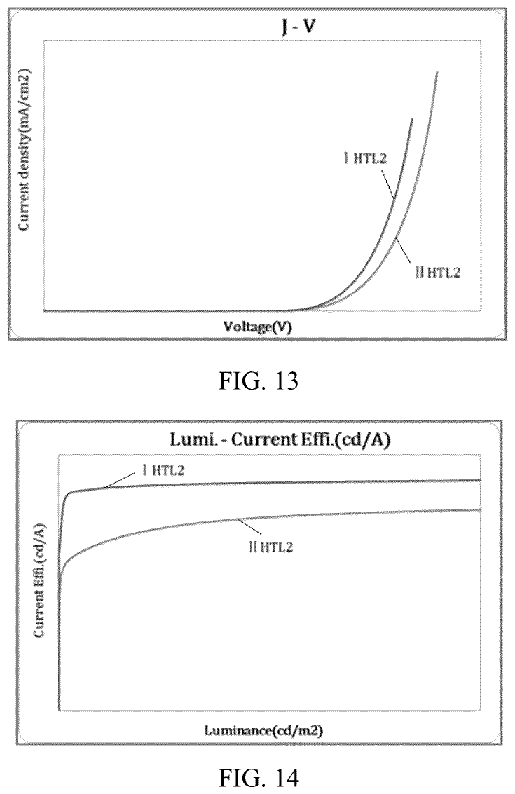

The above conclusions are further verified by experiments, taking a case that the second host material is the same as the material of the second hole transport layer HTL2 as an example, FIGS. 12a and 12b are schematic diagrams of a structure in which different HOMO energy level gaps are set between a second hole transport layer HTL2 and a second electron block layer EBL2 according to an embodiment of the present disclosure; FIG. 13 is a schematic diagram of comparison of a relationship between a current density and a voltage generated by setting two different HOMO energy levels based on the second hole transport layer HTL2 and the second electron block layer EBL2 of FIGS. 12a and 12b according to an embodiment of the present disclosure; FIG. 14 is a schematic diagram of comparison of current efficiencies of two second hole transport layers HTL2 based on FIGS. 12a and 12b according to an embodiment of the present disclosure.

A difference between a HOMO energy level of the second electron block layer EBL2 and a HOMO energy level of a second hole transport layer HTL2 I shown in FIG. 12a is 0.1 eV, i.e., less than 0.15 eV; a difference between a HOMO energy level of the second electron block layer EBL2 and a HOMO energy level of a second hole transport layer HTL2 II shown in FIG. 12b is 0.23 eV, i.e., greater than 0.15 eV.

As shown in FIGS. 12a, 12b, and 13, current densities of the second hole transport layer HTL2 I and the second hole transport layer HTL2 II are quite different under different voltages. Among them, compared with the second hole transport layer HTL2 II, a current density of the second hole transport layer HTL2 I is higher under a same voltage, which can indicate that electron mobility of the second hole transport layer HTL2 II is greater, that is, speeds of injection and transmission of holes by the second charge transport subunit 44 is improved. Under a same current density, performance of the Tandem light emitting device 100 is reduced by 4% compared with a working voltage before optimization.

As shown in FIGS. 12a, 12b, and 14, for the second hole transport layer HTL2 I and the second hole transport layer HTL2 II, a current efficiency of the second hole transport layer HTL2 I is higher than that of the second hole transport layer HTL2 II under same brightness, and a current efficiency of a light emitting device 100 having the second hole transport layer HTL2 I is improved by 13% compared with a current efficiency of a light emitting device 100 having the second hole transport layer HTL2 II.

For a case that the second host material and the material of the second hole transport layer HTL2 are different, a verification process is the same as a verification process of a case that the second host material and the material of the second hole transport layer HTL2 are the same, and repeated parts will not be repeated.

According to the embodiment of the present disclosure, a structure of the first charge generation subunit 42 is optimized and a structure of the second charge generation subunit 43 is optimized to meet their respective preset transmittance conditions and a preset transmittance condition of the charge generation unit; by further optimizing structures of the first charge transport subunit 41 and the second charge transport subunit 44, for example, optimizing an energy level, mobility, etc., a current efficiency and a power efficiency of the light emitting device 100 are improved, and a working voltage of the light emitting device 100 is reduced. Based on the above solutions, the first charge transport subunit 41, the first charge generation subunit 42, the second charge generation subunit 43, and the second charge transport subunit 44 in the charge separation generating unit are optimized in structure and limited in parameters, so that the charge separation generating unit 4 finally satisfies that a transmittance is greater than 68% when a wavelength of visible light is in a range of 380 nm to 480 nm; so that the charge separation generating unit 4 satisfies that a transmittance is greater than 85% when a wavelength of visible light is in a range of 480 nm to 580 nm; so that the charge separation generating unit 4 satisfies that a transmittance is greater than 86% when a wavelength of visible light is in a range of 580 nm to 680 nm. Finally, a working voltage of the Tandem light emitting device 100 is reduced by 6%, a current efficiency is improved by 7%, and a power efficiency is improved by 7%. The working voltage of the Tandem light emitting device 100 is obviously reduced, which is beneficial to applying the Tandem light emitting device 100 to small and medium-sized display panels and reducing a product cost. Performance of the Tandem light emitting device 100 according to the embodiment of the present disclosure is greatly improved compared with that of a conventional Tandem light emitting device 100, thereby enhancing an advantage of the Tandem light emitting device 100 in an aspect of display.

In a second aspect, based on a same inventive concept, an embodiment of the present disclosure also provides a display panel including the light emitting device 100 of any of the above embodiments. The display panel according to the embodiment of the present disclosure has great advantages and is applied to products of small and medium-sized display panels, such as mobile phones, tablet computers, vehicle-mounted devices, and wearable devices. Compared with a conventional Tandem light emitting device 100, the Tandem light emitting device 100 in the display panel improves a power efficiency and a current efficiency and reduces a working voltage, so that a display effect of the Tandem light emitting device 100 on the display panel can be better optimized, such as light emitting brightness and color.

It may be understood that the above implementation modes are only exemplary implementation modes adopted for a purpose of illustrating principles of the present disclosure, however the present disclosure is not limited thereto. For those of ordinary skills in the art, various modifications and improvements may be made without departing from the spirit and substance of the present disclosure, and these modifications and improvements are also considered to be within the scope of the present disclosure.

1. A light emitting device, comprising a first electrode, a second electrode, a plurality of light emitting units disposed between the first electrode and the second electrode, and a charge separation generating unit disposed between adjacent light emitting units;
the charge separation generating unit comprises a first charge transport subunit, a first charge generation subunit, a second charge generation subunit, and a second charge transport subunit disposed in sequence along a direction from the first electrode to the second electrode;
the first charge transport subunit, the first charge generation subunit, the second charge generation subunit, and the second charge transport subunit enable the charge separation generating unit to satisfy that a transmittance is greater than 50% when a wavelength of visible light is in a range of 380 nm to 480 nm; enable the charge separation generating unit to satisfy that a transmittance is greater than 70% when a wavelength of visible light is in a range of 480 nm to 580 nm; and enable the charge separation generating unit to satisfy that a transmittance is greater than 75% when a wavelength of visible light is in a range of 580 nm to 680 nm.

2. The light emitting device according to claim 1, wherein the first charge generation subunit satisfies that a transmittance is greater than 85% when a wavelength of visible light is in the range of 380 nm to 480 nm; the first charge generation subunit satisfies that a transmittance is greater than 95% when a wavelength of visible light is in the range of 480 nm to 580 nm; the first charge generation subunit satisfies that a transmittance is greater than 96% when a wavelength of visible light is in the range of 580 nm to 680 nm; or,
the second charge generation subunit satisfies that a transmittance is greater than 85% when a wavelength of visible light is in the range of 380 nm to 480 nm; the second charge generation subunit satisfies that a transmittance is greater than 95% when a wavelength of visible light is in the range of 480 nm to 580 nm; the second charge generation subunit satisfies that a transmittance is greater than 96% when a wavelength of visible light is in the range of 580 nm to 680 nm.

3. (canceled)

4. The light emitting device according to claim 1, wherein the first charge generation subunit and the second charge generation subunit, which are stacked, serve as one layer of charge generation unit; the charge generation unit satisfies that a transmittance is greater than 75% when a wavelength of visible light is in the range of 380 nm to 480 nm; the charge generation unit satisfies that a transmittance is greater than 93% when a wavelength of visible light is in the range of 480 nm to 580 nm; the charge generation unit satisfies that a transmittance is greater than 95% when a wavelength of visible light is in the range of 580 nm to 680 nm.

5. The light emitting device according to claim 1, wherein the first charge generation subunit comprises a first host material and a first guest material doped in the first host material; the second charge generation subunit comprises a second host material and a second guest material doped in the second host material;
a doping concentration of the first guest material is between 0.4% and 2.0%; a doping concentration of the second guest material is between 0.5% and 1.5%.

6. The light emitting device according to claim 5, wherein the first guest material comprises a metal or a metal salt whose work function orientation is in a range of 2 electron Volts (eV) to 3 eV.

7. The light emitting device according to claim 6, wherein the first guest material comprises at least one of Ytterbium (Yb), Lithium (Li), Cesium (Cs), lithium carbonate, or cesium carbonate.

8. The light emitting device according to claim 5, wherein the second guest material comprises an organic electronic type material and/or an inorganic metal oxide material.

9. The light emitting device according to claim 8, wherein the organic electronic type material comprises 2,3,6,7,10,11-hexocyano-1,4,5,8,9,12-hexazabenzophenanthrene (HATCN);
or,
the inorganic metal oxide material comprises molybdenum oxide.

10. (canceled)

11. The light emitting device according to claim 1, wherein the first charge transport subunit comprises at least one layer of first electron transport layer; or, a first hole block layer and at least one layer of first electron transport layer disposed in sequence along the direction from the first electrode to the second electrode.

12. The light emitting device according to claim 11, wherein the first charge generation subunit comprises an N-type doped charge generation layer;
a difference between a Lowest Unoccupied Molecular Orbital (LUMO) energy level of one first electron transport layer close to the N-type doped charge generation layer and a Lowest Unoccupied Molecular Orbital (LUMO) energy level of the N-type doped charge generation layer is between −0.2 eV and 0.2 eV.

13. The light emitting device according to claim 12, wherein a Lowest Unoccupied Molecular Orbital (LUMO) energy level of one first electron transport layer close to the N-type doped charge generation layer is 0.06 eV.

14. The light emitting device according to claim 12, wherein the first electron transport layer comprises a plurality of layers;
a difference between a Lowest Unoccupied Molecular Orbital (LUMO) energy level of each layer of the first electron transport layer and the Lowest Unoccupied Molecular Orbital (LUMO) energy level of the N-type doped charge generation layer is between −0.2 eV and 0.2 eV.

15. The light emitting device according to claim 11, wherein a third host material of the first electron transport layer comprises a nitrogen-containing heterocyclic derivative or a pyridine derivative; a third guest material doped in the third host material comprises 8-hydroxyquinoline lithium or 8-hydroxyquinoline aluminum analog.

16. The light emitting device according to claim 15, wherein a doping concentration of the third guest material is between 5% and 15%.

17. The light emitting device according to claim 5, wherein the second charge transport unit comprises a second hole transport layer and a second electron block layer sequentially disposed along the direction from the first electrode to the second electrode.

18. The light emitting device according to claim 17, wherein a Highest Occupied Molecular Orbital (HOMO) energy level of the second electron block layer is greater than a Highest Occupied Molecular Orbital (HOMO) energy level of the second hole transport layer, and a difference between the Highest Occupied Molecular Orbital (HOMO) energy level of the second electron block layer and the Highest Occupied Molecular Orbital (HOMO) energy level of the second hole transport layer is less than 0.15 eV.

19. The light emitting device according to claim 17, wherein the second host material is the same as a material of the second hole transport layer; the second charge generation subunit comprises a P-type doped charge generation layer;
a Highest Occupied Molecular Orbital (HOMO) energy level of the P-type doped charge generation layer is smaller than a Highest Occupied Molecular Orbital (HOMO) energy level of the second hole transport layer, and a difference between the Highest Occupied Molecular Orbital (HOMO) energy level of the P-type doped charge generation layer and the Highest Occupied Molecular Orbital (HOMO) energy level of the second hole transport layer is less than 0.15 eV:
or,
wherein the second host material is different from a material of the second hole transport layer; the second charge generation subunit comprises a P-type doped charge generation layer;
a Highest Occupied Molecular Orbital (HOMO) energy level of the P-type doped charge generation layer is larger than a Highest Occupied Molecular Orbital (HOMO) energy level of the second hole transport layer, and a difference between the Highest Occupied Molecular Orbital (HOMO) energy level of the P-type doped charge generation layer and the Highest Occupied Molecular Orbital (HOMO) energy level of the second hole transport layer is less than 0.15 eV.

20. (canceled)

21. The light emitting device according to claim 5, wherein the first host material comprises any one substance selected from pyridine, azine ring, and imidazole analog:
or,
the second host material comprises any one material selected from triphenylamine analog. biphenyl analog, arylamine analog, or carbazole analog.

22. (canceled)

23. The light emitting device according to claim 1, wherein the light emitting unit comprises an emitting layer and a sub-functional layer, the sub-functional layer comprises at least one of a hole injection layer, an electron injection layer, a first hole transport layer, a second electron transport layer, a second hole block layer, and a first electron block layer.

24. A display panel, comprising a light emitting device according to claim 1.
